(19) United States
(12) Patent Application Publication
(10) Pub. No.: US 2016/0020345 A1
(43) Pub. Date: Jan. 21, 2016

(54) METHOD AND DEVICE OF MANUFACTURING COMPOUND-SEMICONDUCTOR THIN-FILM

(71) Applicants: OSAKA UNIVERSITY, Suita-shi, Osaka (JP); KANEKA CORPORATION, Osaka-shi, Osaka (JP)

(72) Inventors: Toshihiko Toyama, Nagoya-shi (JP); Takafumi Konishi, Kakogawa-shi (JP); Ryotaro Tsuji, Akashi-shi (JP)

(73) Assignees: OSAKA UNIVERSITY, Suita-shi, Osaka (JP); KANEKA CORPORATION, Osaka-shi, Osaka (JP)

(21) Appl. No.: 14/773,266

(22) PCT Filed: Mar. 7, 2014
(86) PCT No.: PCT/JP2014/055908

§ 371 Date: Sep. 4, 2015

(30) Foreign Application Priority Data
Mar. 7, 2013 (JP) 2013-045772

(51) Int. Cl. H01L 31/032; H01L 31/0445; C23C 14/54; H01L 31/18

(52) U.S. Cl. CPC H01L 31/0322; H01L 31/18; H01L 31/0445; H01L 31/0326; C23C 14/541

(57) ABSTRACT

The invention is to provide a method of manufacturing I-III-VI and I-II-IV-VI compound semiconductor thin-films, wherein a compound semiconductor crystal is efficiently grown to form a large grain diameter and the content of each of the elements contained in the compound semiconductor can be controlled. A substrate in which a I-III-VI or I-II-IV-VI compound semiconductor thin-film formed on the surface is heated such that a first temperature of the substrate is 100° C. to 700° C., then a non-oxidizing gas heated to a second temperature that is higher than the first temperature is flowed within a chamber so that the compound semiconductor thin-film formed on the surface of the substrate is thermally treated.

### TECHNICAL FIELD

The present invention relates to a method of manufacturing and I-II-IV-VI compound semiconductor thin-films and a manufacturing device thereof.

### BACKGROUND ART

As a potential candidate for renewable energy, attention has been focused on solar cells in recent years, and among them, high efficiency thin-film compound semiconductor solar cells have been actively researched and developed. Among them, I-III-VI compound semiconductors such as Cu—In—S, Cu—In—Se, Cu—In—Ga—S, and Cu—In—Ga—Se have already been commercially released as the light absorbing layer of high-efficiency solar cells, and furthermore, I-II-IV-VI compound semiconductors such as Cu—Zn—Sn—S and Cu—Zn—Sn—Se are also highly promising materials in terms of safety, resources, costs, and the like.

The methods of manufacturing those compound semiconductor thin-films are roughly classified into a sputtering method, a vacuum deposition method, an electro-deposition method, and a coating method.

The sputtering method is a method (for example, see Patent Document 1) of accelerating ions to a metal precursor which is a target, depositing the sputtered target substance into a film on a base member, thereafter heat treating the film in an atmosphere of a gas containing a chalcogen element such as sulfur (S), selenium (Se), or tellurium (Te), and thereby introducing the chalcogen element into the film. The electro-deposition method is a method (for example, see Patent Document 2) of forming a metal precursor thin-film on a base member by electroplating, then heat treating the film in a gas atmosphere and thereby introducing a chalcogen element. The coating method is a method (for example, see Patent Document 3) of applying a solution containing a metal species as a raw material onto a base member in a non-vacuum atmosphere, heating it in an atmosphere containing hydrogen sulfide or sulfur atoms and thereby introducing the sulfide on the surface of a substrate. In each of the methods, in the heat treating process, a chalcogen gas or a hydrogenated chalcogen gas is used as the atmospheric gas for introducing the chalcogen element.

Patent Document 4 teaches a method including a step of depositing a chalcopyrite structure semiconductor thin-film on a base member in an atmosphere of a predetermined gas. During deposition, the temperature of the base member is maintained at 500° C. or less by a heater from the back side of the base member, and furthermore, the front surface side of the base member is heated by an infrared heater, an infrared laser, or the like, so as to keep the temperature of the front surface to 500° C. or more, and the chalcopyrite structure semiconductor thin-film is thus deposited on the base member.

In the following description, a member that serves as a base on which a compound semiconductor thin-film is formed is referred to as a “base member,” and the compound semiconductor thin-film and the base member on which the compound semiconductor thin-film is formed are referred to as a “substrate.”

In Patent Document 4, after the deposition of the chalcopyrite semiconductor thin-film, the entire substrate is thermally treated in an atmosphere of a high-temperature gas.

Patent Document 5 teaches a method of manufacturing a copper indium selenide thin-film, wherein a sputtering method is used to form target substances into a film on a base member, and thereafter a substrate is thermally treated in an atmosphere of a predetermined gas.

Patent Document 6 teaches a method of manufacturing a chalcopyrite structure semiconductor thin-film in which a sputtering method is adopted using a chalcopyrite compound semiconductor as a target to deposit a thin-film of the elements that constitute the chalcopyrite semiconductor, and in an atmosphere containing a desired chalcogen, thermal treatment is performed on the substrate on which the thin-film is deposited.

Patent Document 1: Japanese Patent Application Publication JP2006-210424A

Patent Document 2: Japanese Translation of Internal Application (Translation of PCT Application) JP2009-537997A

Patent Document 3: Japanese Patent Application Publication JP2007-269589A

Patent Document 4: Japanese Patent Application Publication JP08-060359A

Patent Document 5: Japanese Patent Application Publication JP05-263219A

Patent Document 6: Japanese Patent Application Publication JP07-216533A

Although the compound semiconductor thin-film described above is a so-called microcrystalline film that consists of a plurality of fine crystals, as the crystal grain diameter is increased, the grain boundary is reduced, and as a result, a photocurrent can be increased. It is known that the increase in the crystal grain diameter described above can be realized by thermal treating (annealing). Further, the quality of the crystal can also be enhanced by the thermal treating. However, the enhancement significantly depends on conditions of the thermal treatment. For example, in order to achieve a high performance as a solar cell, it is necessary to optimize the conditions of the thermal treatment on the compound semiconductor thin-film so as to control the crystal grain diameter and the quality.

However, in the conditions of the thermal treatment described in the Patent Documents 4 to 6, when thermally treating the substrate on which the semiconductor thin-film is deposited, only the temperature of the substrate or only the temperature of the inside of a chamber that encloses the substrate is controlled. In any one of them, the temperature of the substrate and the temperature of the atmosphere are not both controlled independently.

Therefore, when the temperature of the substrate is raised to increase the crystal grain diameter, the content of the chalcogenide metal component, which is easily volatilized in the thermal treatment, is disadvantageously reduced. When the temperature of the substrate is lowered so as to prevent it from being volatilized, the crystal grain diameter of the film after the thermal treatment is not sufficiently large. In the case where the temperature of the substrate is increased, although it can be expected that the crystal grain diameter will be increased and the quality will be enhanced, there are limitations depending on the heat resistant quality of the base member itself.

### SUMMARY OF THE INVENTION

In the manufacturing of I-III-VI and I-II-IV-VI compound semiconductor thin-films, an object of the present invention is to provide a method of manufacturing a compound semiconductor thin-film that efficiently enhances crystal growth so as to form the compound semiconductor crystal having a large grain diameter and to control the content of each of the elements contained in the compound semiconductor.

### Method to Solve the Problems

The current inventors have invented a manufacturing method and a manufacturing device described below.

A method of manufacturing a compound semiconductor thin-film includes steps wherein a substrate in which a I-III-VI or I-II-IV-VI compound semiconductor thin-film is formed on the surface is heated such that the substrate temperature T1 is 100 to 700° C., a non-oxidizing gas that is heated to a temperature T2 higher than the substrate temperature T1 is flowed within the chamber such that the compound semiconductor thin-film formed on the surface of the substrate is thermally treated.

There is also provided a device of manufacturing a compound semiconductor thin-film, the device including a chamber that houses a substrate in which a I-III-VI or I-II-IV-VI compound semiconductor thin-film is formed on the surface, a first heater that heats such that the temperature (T1) of the substrate is 100° C. to 700° C., and an introduction port that introduces into the chamber a non-oxidizing gas heated to the temperature (T2) higher than the temperature (T1) of the substrate, so that the compound semiconductor thin-film formed on the surface of the substrate is thermally treated.

The temperature T2 of the non-oxidizing gas is preferably higher than the substrate temperature T1 by 100° C. to 800° C. That is, when it is defined that T2−T1=ΔT, ΔT preferably falls within a range of 100° C. to 800° C.

When the non-oxidizing gas flows within the chamber, one type or two or more types of metal compounds preferably flow together with the non-oxidizing gas, the compounds being selected from a group consisting of a metal sulfide, a metal selenide, a metal oxide, a metal salt, a metal alkylide, and a metal complex, wherein the metal is a metal that is constituting the compound semiconductor thin-film. Thereby, it becomes possible to control the composition of the compound semiconductor thin-film and to enhance the crystal growth. Among the above compounds, a compound that does not contain an element that is not in the compound semiconductor thin-film is more preferable in order to keep the purity of the compound semiconductor thin-film. The sulfide and the selenide are further preferable, and the sulfide and the selenide of tin are most preferable. Those are sublimed or vaporized to flow in the heated non-oxidizing gas. Either of sulfur and selenium or both may be sublimed, and may flow together with the non-oxidizing gas.

The temperature T2 of the non-oxidizing gas to be flowed is preferably 500° C. to 1000° C., and is more preferably 600° C. to 900° C. When the temperature T2 is set at 500° C. or more, an effect of enhancing the crystal growth is obtained, and when it is set at 1000° C. or less, it becomes possible to obtain an effect of suppressing changes in composition by the vaporization of the compound semiconductor and suppressing the thermal deformation of the base member.

The non-oxidizing gas is preferably one or more gases selected from a group consisting of nitrogen, argon, helium, hydrogen, hydrogen sulfide, and hydrogen selenide.

Flowing an inert gas such as nitrogen or argon mixed with hydrogen sulfide or hydrogen selenide is particularly preferable. However, when the concentration of hydrogen sulfide or hydrogen selenide is too high, corrosion of the device takes place and health problems arise. Therefore, the concentration of the hydrogen sulfide or the hydrogen selenide is preferably 0.1% to 30% in volume, and is more preferably 0.5% to 10% in volume.

The substrate is, in one example, a substrate in which the I-III-VI or I-II-IV-VI compound semiconductor thin-film is formed on a base member to which conductivity is provided in at least a part of the surface or the entire surface thereof.

The compound semiconductor of the present invention is preferably Cu—In—S, Cu—In—Se, Cu—In—Ga—S, Cu—In—Ga—Se, Cu—Zn—Sn—S, Cu—Zn—Sn—Se, or solid solutions thereof. Those films can be applied to useful devices such as a photovoltaic device. In terms of the availability and the cost of raw materials, Cu—Zn—Sn—S and Cu—Zn—Sn—Se and the solid solutions thereof are more preferable.

The manufacturing device of the compound semiconductor thin-film according to the present invention, may comprise a chamber that includes two interiors connecting with each other, wherein the non-oxidizing gas is heated to a temperature (T2) in a first interior that is disposed on the upstream side, the substrate is heated to a temperature (T1) in a second interior that is disposed on the downstream side, and the non-oxidizing gas flows from the first interior to the second interior.

In the compound semiconductor thin-film obtained by the manufacturing method of the present invention, an average crystal grain diameter thereof is typically 200 nm to 5 μm. The crystal structure of the compound semiconductor is preferably a chalcopyrite type or a kesterite type in terms of achieving high performance as a photovoltaic device. The kesterite type is more preferable in terms of the availability and the cost of raw materials.

The compound semiconductor thin-film of the invention is used as a light absorbing layer so that a photovoltaic device is produced.

As described above, according to the present invention, it is possible to manufacture a high-quality compound semiconductor thin-film with an inexpensive and simple method.

When it is used as a photovoltaic device, photoelectric conversion efficiency is high.

In addition to the advantages, features, and effects of the present invention described above, still other advantages, features, and effects will be further clarified by the following description of a preferred embodiment with reference to accompanying drawings.

### BRIEF DESCRIPTION OF THE DRAWINGS

FIG. 1 is a schematic cross-sectional view showing a manufacturing device of a compound semiconductor thin-film.

FIG. 2 is a graph showing changes over time in the temperature T2 of an interior 1b disposed on the upstream side and changes over time in the temperature T1 of an interior 1a disposed on the downstream side.

FIG. 3 is a photograph showing a scanning electron microscopy (SEM) image of a CZTS thin-film before thermal treatment in Example 1.

FIG. 4 is a photograph showing an SEM image of the CZTS thin-film after the thermal treatment in Example 1.

FIG. 5 is a photograph showing an SEM image of the CZTS thin-film after the thermal treatment in Example 2.

FIG. 6 is a photograph showing an SEM image of the CZTS thin-film after the thermal treatment in Example 3.

FIG. 7 is a photograph showing an SEM image of the CZTS thin-film after the thermal treatment in Comparative Example 1.

FIG. 8 is a photograph showing an SEM image of the CZTS thin-film after the thermal treatment in Example 4.

FIG. 9 is a photograph showing an SEM image of the CZTS thin-film after the thermal treatment in Example 5.

FIG. 10 is a photograph showing an SEM image of the CZTS thin-film after the thermal treatment in Example 6.

FIG. 11 is a photograph showing an SEM image of the CZTS thin-film before the thermal treatment in Comparative Example 2.

FIG. 12 is a photograph showing an SEM image of the CZTS thin-film after the thermal treatment in Comparative Example 2.

### DETAILED DESCRIPTION

A preferred embodiment of the present invention will be described below. The scope of the present invention is indicated by the claims, and it is intended that meanings equivalent to the claims and modifications within the scope are described in the preferred embodiment.

In the preferred embodiment of the present invention, the thin-film of a I-III-VI compound semiconductor or a I-II-IV-VI compound semiconductor formed on a base member is used as a substrate. Although the method of manufacturing the substrate is not particularly limited, a reactive sputtering method in which a single sintered target and the base member are arranged within a chamber and alternating-current power is applied between both of them is preferably used. It is possible to manufacture it simply and inexpensively in one step in the reactive sputtering method. For example, a Cu₂ZnSnS₄ sintered target is used, and a Cu—Zn—Sn—S (CZTS) thin-film is formed.

Other methods can be adopted, for example, a method of sputtering metals of group I and group III or metals of group I, group II, and group IV while introducing hydride gas of a group VI element. Another method is forming metals of group I and group III or metals of group I, group II, and group IV into a film with a method such as sputtering, vacuum deposition, electro-deposition, or coating, and thereafter processing the film with a single element of group VI or with a compound containing a group VI element.

The base member used in the preferred embodiment of the present invention, is not particularly limited as long as it can withstand thermal treatment. For example, soda lime glass, heat-resistant glass, quartz glass, a polyimide (PI) film, a polyethylene naphthalate (PEN) film, and the like can be used. In particular, when a photovoltaic element is manufactured, soda lime glass and heat-resistant glass containing sodium in the components are preferable, since a minute amount of sodium ions are desirably diffused in the compound semiconductor thin-film. Moreover, when a photovoltaic device is manufactured, a base member in which a conductive film is formed on its surface is preferably used, since an electrode is necessary for extracting current. As the conductive film, molybdenum (Mo), gold, silver, aluminum, nickel, indium tin oxide (ITO), indium tungsten oxide (IWO), tin oxide, zinc oxide, and the like can be used. When a glass base member is used, Mo is preferable, since its linear expansion coefficient is nearly the same as that of glass, and thus it is unlikely to peel off from the glass base member.

Examples of the I-III-VI compound semiconductor include Cu—In—S, Cu—In—Se, Cu—In—Ga—S, Cu—In—Ga—Se, Cu—In—Te, Cu—In—Ga—Te, Ag—In—S, Ag—In—Se, Ag—In—Te, Cu—Al—S, Cu—Al—Se, Cu—In—Al—S, Cu—In—Al—Se, Ag—Al—S, Ag—Al—Se, and the solid solutions thereof. Examples of the I-II-IV-VI compound semiconductor include Cu—Zn—Sn—S, Cu—Zn—Sn—Se, Cu—Zn—Ge—S, Cu—Zn—Ge—Se, Cu—Zn—Sn—Te, Cu—Zn—Ge—Te, Ag—Zn—Sn—S, Ag—Zn—Sn—Se, Cu—Zn—Pb—S, Cu—Zn—Pb—Se, Ag—Zn—Pb—S, Ag—Zn—Pb—Se, and the solid solutions thereof. Among them, Cu—In—S, Cu—In—Se, Cu—In—Ga—S, Cu—In—Ga—Se, Cu—Zn—Sn—S, Cu—Zn—Sn—Se, and the solid solutions thereof are preferable since they are excellent in performance as the photovoltaic device, whereas in terms of the availability and the cost of raw materials, Cu—Zn—Sn—S, Cu—Zn—Sn—Se, and the solid solutions thereof are more preferable.

A thermal treatment step will be described. In one preferred embodiment of the present invention, a substrate on which the compound semiconductor thin-film is formed is heated such that the substrate temperature T1=100° C. to 700° C., a non-oxidizing gas that is heated to a temperature of T2 higher than T1 is introduced thereto, and the thermal treatment is carried out. Here, T2 is preferably higher than T1 by 100° C. to 800° C. (T2−T1=ΔT, ΔT=100° C. to 800° C.). Among them, T2 is preferably higher than T1 by 200° C. to 800° C.

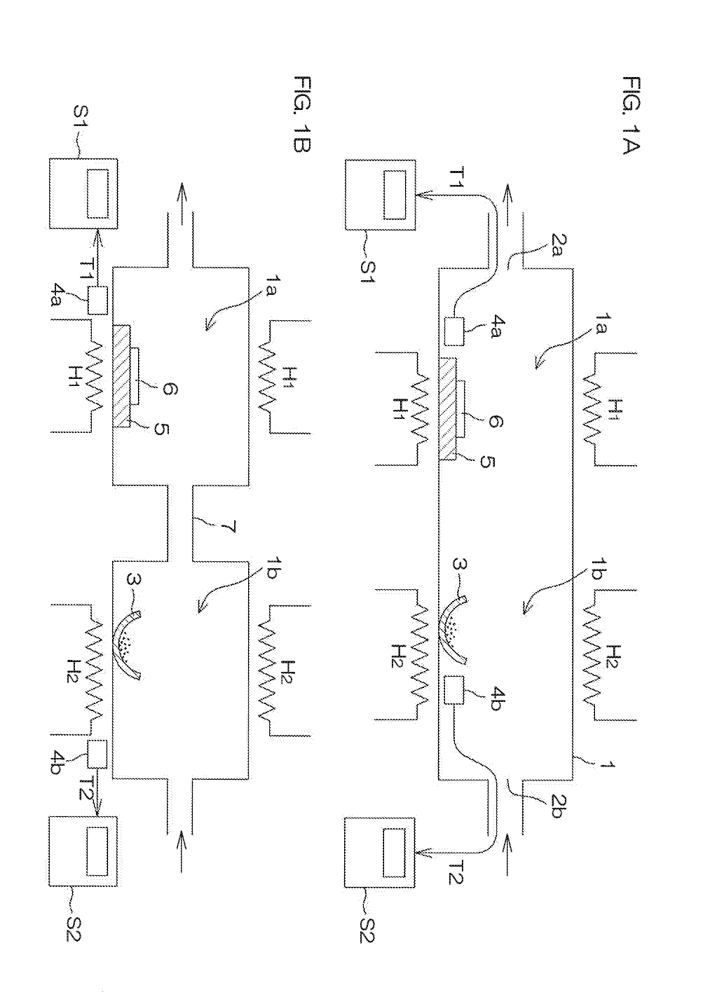

FIG. 1 at (a) is a schematic cross-sectional view showing a manufacturing device of the compound semiconductor thin-film. The manufacturing device includes a chamber 1 that is partitioned into two interiors 1a and 1b that are connected to each other. Examples of the material of the chamber 1 include quartz glass, heat-resistant glass, ceramics, graphite, and stainless steel. In the interior 1b on the upstream side, an introduction port 2b for introducing the non-oxidizing gas is provided. In the interior 1a on the downstream side, a discharge port 2a for discharging the non-oxidizing gas is provided. In this example, there is no part between the two interiors 1a and 1b that is resistant to the flowing of the non-oxidizing gas, and the cross sectional area of the chamber 1 is substantially constant through the two interiors 1a and 1b. Hence, the non-oxidizing gas flows smoothly from the interior 1b on the upstream side to the interior 1a on the downstream side.

Around each of the two interiors 1a and 1b, electric heaters H1 and H2 are independently arranged. Each of the electric heaters H1 and H2 is surrounded by a thermal insulation material (not shown). These electric heaters H1 and H2, the thermal insulation material, and a power supply device (not shown) that independently supplies power to each of the electric heaters H1 and H2, constitute an electric furnace having two heating zones. Instead of the electric heater, an infrared lamp may be adopted to irradiate with infrared rays.

As shown in FIG. 1 at (b), a part that connects the two interiors 1a and 1b communicating with each other may be formed with a tube 7 having a relatively small cross sectional area. In this case, although the flow resistance to the gas flowing through the chamber 1 is increased, the heat insulation between the interiors 1a and 1b is enhanced, and thus it becomes easy to independently control the temperature of each of the interiors 1a and 1b.

In the interior 1b on the upstream side, a temperature detection portion 4b such as a thermocouple is provided. The temperature detection portion 4b is connected via an electric wire to a temperature measuring device S2, and the temperature T2 of the interior 1b is measured by the temperature measuring device S2. By the temperature T2, the temperature of the non-oxidizing gas flowing through the interior 1b can be estimated.

In the interior 1a on the downstream side, a temperature detection portion 4a such as a thermocouple is provided. The temperature detection portion 4a is connected to a temperature measuring device S1, and the temperature T1 of the interior 1a is measured by the temperature measuring device S1. By the temperature T1, the temperature of a substrate 6 arranged in the interior 1a can be estimated.

The temperature detection portions 4a and 4b are arranged in the interiors 1a and 1b shown in FIG. 1 at (a). They may be arranged in other positions where the temperatures of the interiors 1a and 1b can be estimated. For example, as shown in FIG. 1 at (b), the temperature detection portions 4a and 4b may be inside the electric furnace and outside the chamber 1.

In the thermal treatment process, one type or more types of metal compound gas preferably flow together with the non-oxidizing gas. An example of the compound is selected from a group consisting of a metal sulfide, a metal selenide, a metal oxide, a metal salt, a metal alkylide, and a metal complex, wherein the metal constitutes the compound semiconductor thin-film. In this manner, the composition of the compound semiconductor thin-film can be accurately controlled and the crystal growth is enhanced. Examples of the sulfide include CuS, Cu₂S, InS, In₂S₃, GaS, Ga₂S₃, ZnS, SnS, and SnS₂; examples of the selenide include CuSe, Cu₂Se, CuSeO₄, InSe, In₂Se, In₂Se₃, GaSe, Ga₂Se₃, ZnSe, ZnSeO₃, and SnSe; examples of the oxide include CuO, Cu₂O, In₂O₃, Ga₂O₃, ZnO, ZnAl₂O₄, SnO, and SnO₂; examples of the salt include CuBr, CuBr₂, CuCO₃, CuCl, CuCl₂, CuSO₄, InBr₃, InCl₃, In(NO₃)₃, In₂ (SO₄)₃, GaBr₃, GaCl₃, Ga₂(NO₃)₃, ZnBr₂, ZnCl₂, Zn(NO₃)₂, ZnSO₄, Zn₂P₂O₇, SnBr₂, SnCl₂, SnCl₄, SnSO₄, and oxalic acid first tin; examples of the alkylide include copper acetylide, Gilman reagent, dimethyl zinc, diethyl zinc, diphenyl zinc, trimethyl zinc, triethyl zinc, bistributyltin oxide, n-butyl tin trichloride, tributyltin chloride, acetic acid triphenyl tin, triphenyltin hydroxide, trimethyl indium, triethyl indium, trimethyl gallium, and triethyl gallium; examples of the complex include copper phthalocyanine, tetraammine copper complex, cupric acetate, copper bis(diisobutyrylmethanate), zinc acetate, and tetraammine zinc complex. Among them, a compound that does not contain an element that is not included in the compound semiconductor thin-film is more preferable, since the purity of the compound semiconductor thin-film is kept. The sulfide and the selenide are further preferable and the sulfide and the selenide of tin are most preferable. Either of sulfur and selenium or both may be sublimed to flow together with the non-oxidizing gas.

In thermal treatment process, (a) a single metal element that constitutes those compound semiconductor thin-films, (b) one type or more types of the metal compounds selected from a group consisting of a sulfide, a selenide, an oxide, a salt, an alkylide, and a complex, or (c) sulfur or selenium may be housed in a heat-resistant container 3 arranged in the interior 1b on the upstream side, so that it is sublimed to flow. Note that the heat-resistant container 3 is not an essential constituent of the invention and it is also possible to carry out the thermal treatment without the heat-resistant container 3.

In the interior 1a on the downstream side, the substrate on which the compound semiconductor thin-film is formed is provided. The substrate 6 is placed on a stage 5. Since the deformation of the stage 5 by a high temperature may induce the substrate to be warped, the material of the stage 5 is preferably carbon or ceramics, which are unlikely to be deformed by a high temperature.

In order for the heated non-oxidizing gas to flow into the chamber 1, the electric heater H2 is energized to keep the interior 1b substantially at the temperature T2. At the same time, in order for the substrate 6 to be heated, the electric heater H1 is also preferably energized to keep the interior 1a substantially at the temperature T1. The relationship between the temperature T1 and the temperature T2, as described above, is that the temperature T2 is higher than the temperature T1. In the temperature conditions described above, under atmospheric pressure, the non-oxidizing gas is introduced from the introduction port 2b. The non-oxidizing gas thus introduced from the introduction port 2b may be preheated in advance.

As described above, the non-oxidizing gas heated in the interior 1b on the upstream side reaches the substrate 6 on the downstream side, then the non-oxidizing gas heats the compound semiconductor thin-film at a temperature higher than the substrate temperature T1.

If the substrate temperature T1 is excessively high, deformation of the base member may be caused, and the compound semiconductor thin-film may peel off. In the preferred embodiment of the present invention, the substrate temperature T1 is kept low, the temperature of the flowing gas is kept at a relatively high temperature, the above disadvantages are thus suppressed, and the compound semiconductor thin-film is efficiently heated, with the result that the crystal growth is enhanced.

The substrate temperature T1 is preferably 300° C. to 700° C. and is more preferably 400° C. to 600° C., because the crystal growth effect is enhanced while suppressing the deformation of the base member.

The temperature T2 of the non-oxidizing gas is set at a temperature higher than T1, and thus it is possible to efficiently facilitate the crystal growth while suppressing changes in the composition of the compound semiconductor and the deformation of the base member. The temperature T2 of the non-oxidizing gas is preferably 500° C. to 1000° C.

When a CZTS thin-film is used as the compound semiconductor thin-film, in the thermal treatment process, a sulfide of Sn that is one type of constituent elements of the CZTS thin-film, may be placed in the container 3 in the interior 1b on the upstream side. The tin sulfide is vaporized by heating at the temperature T2. The vapor acts on the CZTS thin-film to enhance the crystal growth. As described above, a compound or a single element that is contained in the constituent element of the CZTS thin-film is sublimed or evaporated to flow together with the non-oxidizing gas of a high temperature. With the result, it may be possible to prevent the removal of a specific component from the CZTS thin-film and to control the composition of the CZTS thin-film.

By the manufacturing method of the present invention, as compared with a conventional method, the crystal growth of the compound semiconductor thin-film can be enhanced, and its average crystal grain diameter can be typically about 200 nm to 5 μm, and preferably about 1 μm to 5 μm. It is also possible to achieve a crystal grain diameter which exceeds the film thickness, which is an effect that cannot be realized even by any conventional method. Examples of the crystal structure of the compound semiconductor are a chalcopyrite type, a wurtzite type, a roquesite type, a gallite type, a stannite type, a wurtz stannite type, and a kesterite type. Among them, the chalcopyrite type or the kesterite type is preferable since it has a high performance as a photovoltaic device. The kesterite type is more preferable in terms of the availability and the cost of raw materials.

After the thermal treatment process described above is performed on the CZTS thin-film, a photovoltaic device is produced by forming a buffer layer on the CZTS thin-film by a chemical bath deposition (CBD) method, and furthermore, forming a transparent conductive layer by a sputtering method or a chemical vapor deposition method (CVD method). As the buffer layer, cadmium sulfide (CdS), or zinc sulfide (ZnS) are generally used. In the CBD method to fabricate the cadmium sulfide layer, the substrate is immersed in an aqueous ammonia solution of cadmium iodide and thiourea, and is heated to about 70° C. Thereafter, as the transparent conductive layer, zinc oxide (ZnO), indium tin oxide (ITO), or the like is formed on the film by a sputtering method or a CVD method. In the photovoltaic device, a grid electrode for power collection may further be formed by the vacuum deposition of silver or aluminum.

### EXAMPLES

Examples of the present invention will be described. Members identified with the same reference symbols as those in FIG. 1 are assumed to substantially represent the same members, even though they are different in name.

The conditions of thermal treatment on CZTS thin-films adopted in Examples 1 to 6 and Comparative Examples 1 and 2 will be shown in Table 1. The average grain diameter thereof and the conversion efficiency of CZTS photovoltaic devices manufactured are also shown in Table 1.

TABLE 1

| | | | | | | Average | |
|---|---|---|---|---|---|---|---|
| | | | | | | crystal | |
| | | | | | | grain | Conversion |
| | | | Temperature | Temperature | | diameter | efficiency |
| | Gas | Flow rate | T1 | T2 | Additive | (μm) | (%) |
| Example 1 | N₂ | 400 mL/min | 550° C. | 850° C. | SnS₂ 5 mg | 4.45 | 1.63 |
| Example 2 | N₂ | 480 mL/min | 550° C. | 850° C. | SnS₂ 5 mg | 3.34 | 6.42 |
| | H₂S | 20 mL/min | | | | | |
| Example 3 | N₂ | 50 mL/min | 550° C. | 850° C. | SnS₂ 5 mg | 2.06 | 5.46 |
| | H₂S | 2.5 mL/min | | | Se 52 mg | | |
| Comparative | N₂ | 100 mL/min | 550° C. | 550° C. | — | 0.49 | 0.88 |
| Example 1 | | | | | | | |
| Example 4 | N₂ | 47.5 mL/min | 550° C. | 650° C. | — | 0.75 | — |
| | H₂S | 2.5 mL/min | | | | | |
| Example 5 | N₂ | 47.5 mL/min | 550° C. | 750° C. | — | 0.79 | — |
| | H₂S | 2.5 mL/min | | | | | |
| Example 6 | N₂ | 47.5 mL/min | 550° C. | 850° C. | — | 1.13 | — |
| | H₂S | 2.5 mL/min | | | | | |
| Comparative | N₂ | 47.5 mL/min | 50° C. | 850° C. | — | <0.05 | — |
| Example 2 | | 2.5 mL/min | | | | | |

### Example 1

With a CZTS sintered target, a CZTS thin-film was formed on the Mo film on soda lime glass in which the Mo film was formed on its surface by a RF magnetron sputtering method. The conditions of the film formation of the CZTS thin-film were set such that the substrate temperature was 230° C., the applied power was 150 W, the pressure of the film formation was 2 Pa, an H₂S/Ar mixture gas was used as the atmosphere gas, and the partial pressure of H₂S was 0.5. The thickness of the film obtained was 1 μm.

The substrate 6 on which the CZTS thin-film obtained as described above was placed on the carbon stage 5, put into a quartz tube 1 and set in the interior 1a on the downstream side of a two-zone electric furnace having substantially the same configuration as shown in FIG. 1 at (a). 5 mg of SnS₂ was put into a crucible 3 and the crucible 3 was set in the interior 1b on the upstream side in the same quartz tube 1. An operation in which the quartz tube 1 was vacuumed and nitrogen gas was introduced was performed three times, and a gas within the quartz tube 1 was thus replaced by the nitrogen gas.

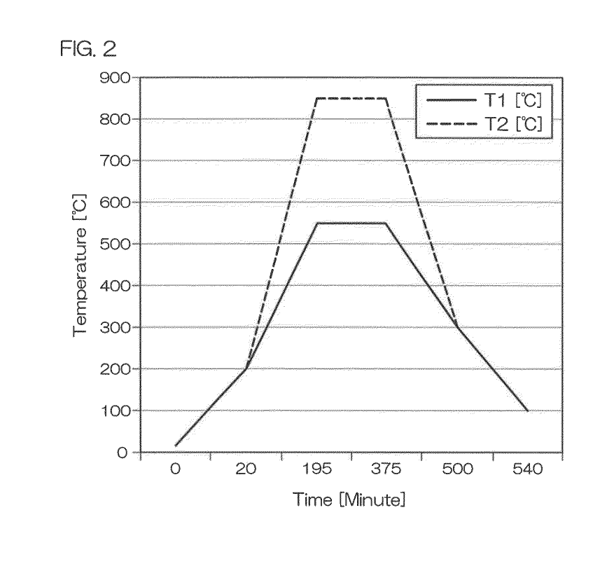

In a thermal treatment process, while flowing the nitrogen gas (400 mL/min) according to a temperature profile shown in FIG. 2, the interior 1a for the heating of the substrate where the substrate 6 with the CZTS thin-film was set, and the interior 1b on the upstream side for the gas heating, were heated at the temperatures T1, and T2, respectively. At first, the heating was performed with the same power to raise the temperature T1 and the temperature T2 together. Then the power of the heater H2 of the interior 1b was increased halfway such that the temperature T2 of the interior 1b was higher than the temperature T1 of the interior 1a. In the equilibrium state, the temperature T2 was 850° C., the temperature T1 was 550° C., and the temperature difference was 300° C. This equilibrium state was maintained for 180 minutes. Thereafter, the power of the heaters H1 and H2 were slightly reduced or interrupted, and thus the temperature T1 and the temperature T2 were lowered together.

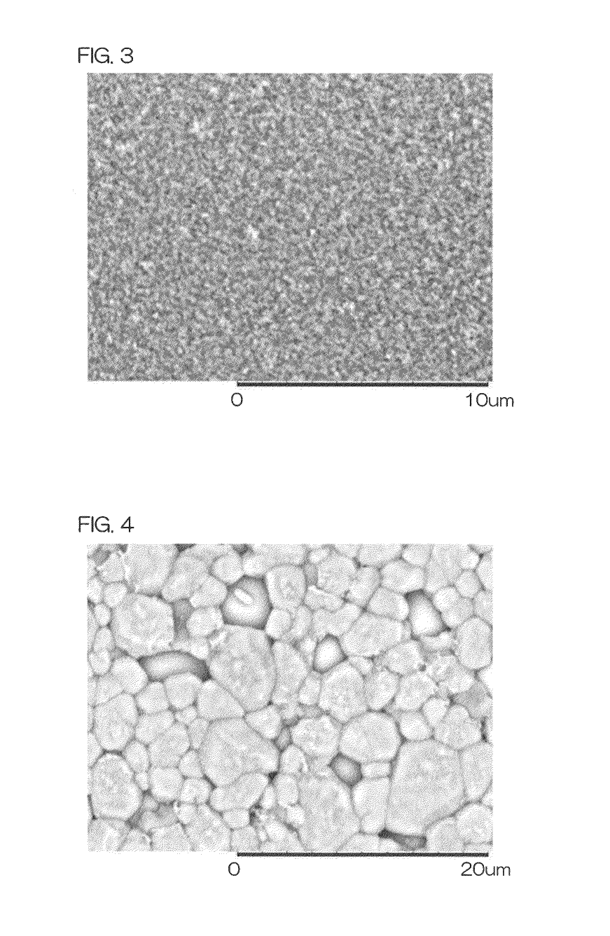

Scanning electron microscopy (SEM) images of the CZTS thin-film before and after the thermal treatment are shown in FIGS. 3 and 4, respectively.

In FIG. 3, crystal grains were so small that they could not be confirmed, although the magnification of FIG. 3 was higher (about twice higher) than that of FIG. 4. However, in FIG. 4, it was confirmed that the crystal grain diameter had increased. It is shown in FIG. 4 that the largest crystal grain diameter was about 5 μm, and that the crystal grew due to the thermal treatment.

To determine the average crystal grain diameter, the grain diameters of about 20 grains in the photograph were each measured and then averaged (the same applies to the Examples and the Comparative Examples below). In FIG. 4, the average crystal grain diameter was 4.45 μm.

On the CZTS thin-film on which the thermal treatment was performed as described above, a CdS layer was formed with a CBD method described below. Specifically, 2.02 g of thiourea and 63 mg of cadmium iodide were added to 72 mL of distilled water in a beaker and were dissolved, and 18 mL of 28% aqueous ammonia was added. The CZTS thin-film was immersed in this solution, and heated in a hot water bath of 70° C. for 20 minutes. Thereafter, the substrate was taken out, washed with distilled water, and dried. On the CdS layer, with a magnetron sputtering device, a ZnO film (film thickness of 50 nm) and an ITO film (film thickness of 100 nm) were formed, and a finger electrode of silver was vacuum-deposited thereon, with the result that the CZTS photovoltaic device was manufactured.

The obtained CZTS photovoltaic device was scribed into a size of 5 mm×8 mm, and the photoelectric conversion characteristics were evaluated by using a solar simulator (WXS-50S-1.5, AM 1.5 G) and an IV measuring device (IV02110-10AD1) made by Wacom Electric Co., Ltd. The measurement was performed at an air mass (AM) of 1.5 G and at a substrate temperature of ° C. Jsc=11.8 mA/cm², Voc=0.38 V, FF=0.36, and the conversion efficiency was 1.63%.

### Example 2

With a CZTS sintered target, a CZTS thin-film was formed on the Mo film on soda lime glass in which the Mo film was formed on its surface by the RF magnetron sputtering method. The conditions of the film formation of the CZTS thin-film were set such that the substrate temperature was 230° C., the applied power was 150 W, the pressure of the film formation was 2 Pa, an H₂S/Ar mixture gas was used as the atmosphere gas, and the partial pressure of H₂S was 0.5. The thickness of the film obtained was 1.1 μm.

The substrate 6 on which the CZTS thin-film obtained as described above was placed on the carbon stage 5, put into a quartz tube 1, and set in the interior 1a on the downstream side of a two-zone electric furnace having substantially the same configuration as that shown in FIG. 1 at (a). 5 mg of SnS₂ was put into a crucible 3 and the crucible 3 was set in the interior 1b on the upstream side in the same quartz tube 1. An operation of vacuuming the quartz tube 1 and introducing the nitrogen gas was performed three times, and a gas within the quartz tube 1 was thus replaced by the nitrogen gas.

At the time of thermal treatment, while flowing H₂S gas (20 mL/min) and the nitrogen gas (480 mL/min) under the temperature profile shown in FIG. 2, the interior 1a for the heating of the substrate where the substrate 6 with the CZTS thin-film formed was set, and the interior 1b on the upstream side for the gas heating, were heated at the temperatures T1, and T2, respectively. At the time when 375 minutes had elapsed since the start of the heating, that is, when T1 started to fall from 550° C., the H₂S gas was stopped, and only the nitrogen gas was flowed. An SEM image of the CZTS thin-film after the thermal treatment is shown in FIG. 5. It is seen that the crystal grew due to the thermal treatment. In FIG. 5, the average crystal grain diameter was 3.34 μm.

Based on the CZTS thin-film that was thermally treated as described above, the CZTS photovoltaic device was manufactured in the same manner as that of Example 1. The obtained CZTS photovoltaic device was scribed into a size of 5 mm×8 mm, and the photoelectric conversion characteristics were evaluated. The measurement was performed at an air mass (AM) of 1.5 G and at a substrate temperature of 25° C., and Jsc=18.7 mA/cm², Voc=0.64 V, FF=0.54, and the conversion efficiency was 6.42%. It is considered that the conversion efficiency was enhanced as compared with Example 1 as described above because of the effect of the flow of the H₂S gas together with the nitrogen gas.

### Example 3

With a CZTS sintered target, a CZTS thin-film was formed on the Mo film on the soda lime glass base member in which the Mo film was formed on its surface by the RF magnetron sputtering method. The conditions of the film formation of the CZTS thin-film were set such that the substrate temperature was 230° C., the applied power was 150 W, the pressure of the film formation was 2 Pa, an H₂S/Ar mixture gas was used as the atmosphere gas, and the partial pressure of H₂S was 0.5. The thickness of the film obtained was 0.6 μm.

The substrate 6 on which the CZTS thin-film obtained as described above was placed on the carbon stage 5, put into a quartz tube 1, and set in the interior 1a on the downstream side of a two-zone electric furnace having substantially the same configuration as shown in FIG. 1 at (a). 5 mg of SnS₂ and 52 mg of Se were each put into a crucible 3 and the crucible 3 was set in the interior 1b on the upstream side in the same quartz tube 1. An operation of vacuuming the quartz tube 1 and introducing nitrogen gas was performed three times, and a gas within the quartz tube 1 was thus replaced by the nitrogen gas.

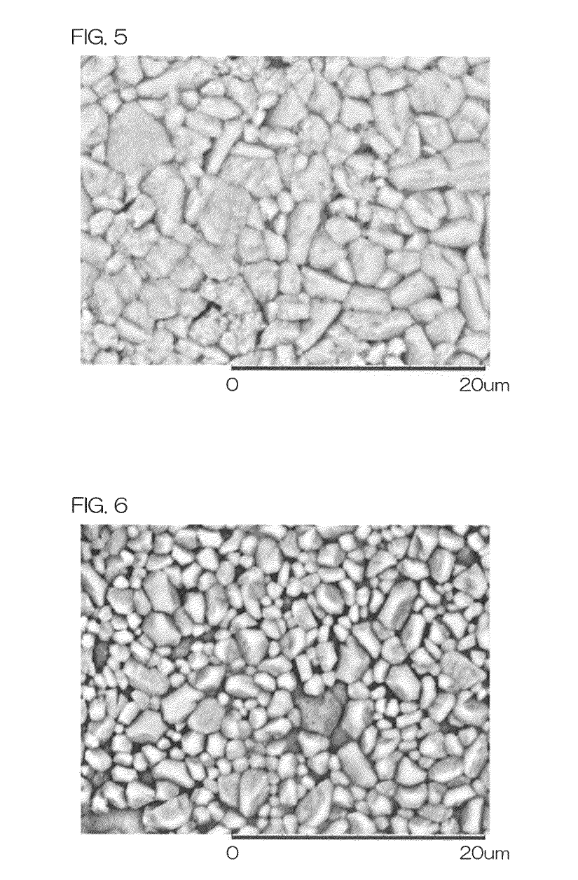

At the time of thermal treatment, while flowing H₂S gas (2.5 mL/min) and the nitrogen gas (50 mL/min), under the temperature profile shown in FIG. 2, the interior 1a for the heating of the substrate where the substrate 6 with the CZTS thin-film formed was set, and the interior 1b on the upstream side for the gas heating, were heated at the temperatures T1, and T2, respectively. At the time when 375 minutes had elapsed since the start of the heating, that is, when T1 started to fall from 550° C., the H₂S gas was stopped, and only the nitrogen gas was flowing. An SEM image of the CZTS thin-film after the thermal treatment is shown in FIG. 6 which shows that the crystal grew due to the thermal treatment. In FIG. 6, the average crystal grain diameter was 2.06 μm.

Based on the CZTS thin-film that was thermally treated as described above, the CZTS photovoltaic device was manufactured in the same manner as that of Example 1. The obtained CZTS photovoltaic device was scribed into a size of 5 mm×8 mm, and the photoelectric conversion characteristics were evaluated. The measurement was performed at an air mass (AM) of 1.5 G and at a substrate temperature of 25° C., and Jsc=16.8 mA/cm², Voc=0.60 V, FF=0.54, and the conversion efficiency was 5.46%.

### Comparative Example 1

With a CZTS sintered target, a CZTS thin-film was formed on the Mo film on soda lime glass in which the Mo film was formed on its surface by the RF magnetron sputtering method. The conditions of the film formation of the CZTS thin-film were set such that the substrate temperature was 230° C., the applied power was 150 W, the pressure of the film formation was 2 Pa, an H₂S/Ar mixture gas was used as the atmosphere gas, and the partial pressure of H₂S was 0.5. The thickness of the film obtained was 1 μm.

The substrate on which the CZTS thin-film was formed as described above was placed on the carbon stage, and put into a quartz tube, and an operation of vacuuming the quartz tube and introducing nitrogen gas was performed three times, and a gas within the quartz tube was thus replaced by the nitrogen gas.

In a thermal treatment process, while flowing the nitrogen gas (100 mL/min), the substrate with the CZTS thin-film formed was set in the quartz tube, and the quartz tube was heated at a temperature of 550° C. for 3 hours. The temperatures of the two interiors in the quartz tube were not independently controlled. An SEM image of the CZTS thin-film after the thermal treatment is shown in FIG. 7. It is seen that the crystal grain diameter was very small as compared with FIGS. 4 to 6. In FIG. 7, the average crystal grain diameter was 0.49 μm.

Based on the CZTS thin-film thermally treated as described above, the CZTS photovoltaic device was manufactured in the same manner as that of Example 1. The obtained CZTS photovoltaic device was scribed into a size of 5 mm×8 mm, and the photoelectric conversion characteristics were evaluated. The measurement was performed at an air mass (AM) of 1.5 G and at a substrate temperature of 25° C., and Jsc=4.7 mA/cm², Voc=0.41 V, FF=0.47, and the conversion efficiency was 0.88%.

### Examples 4 to 6

With a CZTS sintered target, a CZTS thin-film was formed on the Mo film on soda lime glass in which the Mo film was formed on its surface by the RF magnetron sputtering method. The conditions of the film formation of the CZTS thin-film were set such that the substrate temperature was 230° C., the applied power was 150 W, the pressure of the film formation was 2 Pa, an H₂S/Ar mixture gas was used as the atmosphere gas, and the partial pressure of H₂S was 0.5. The thickness of the film obtained was 1 μm.

The substrate 6 on which the CZTS thin-film obtained as described above was formed was placed on the carbon stage 5, put into the quartz tube 1 and set in the interior 1a on the downstream side of the two-zone electric furnace having substantially the same configuration as shown in FIG. 1 at (a). An operation of vacuuming the quartz tube 1 and introducing nitrogen gas was performed three times, and a gas within the quartz tube was thus replaced by the nitrogen gas.

In a thermal treatment process, while flowing H₂S gas (2.5 mL/min) and nitrogen gas (47.5 mL/min), the temperature of the interior 1a for the heating of the substrate, where the substrate with the CZTS thin-film formed was set, was set to 550° C., and the temperature of the interior 1b on the upstream side for the gas heating was set to 650° C. (Example 4), 750° C. (Example 5), and 850° C. (Example 6), and they were each heated for 3 hours.

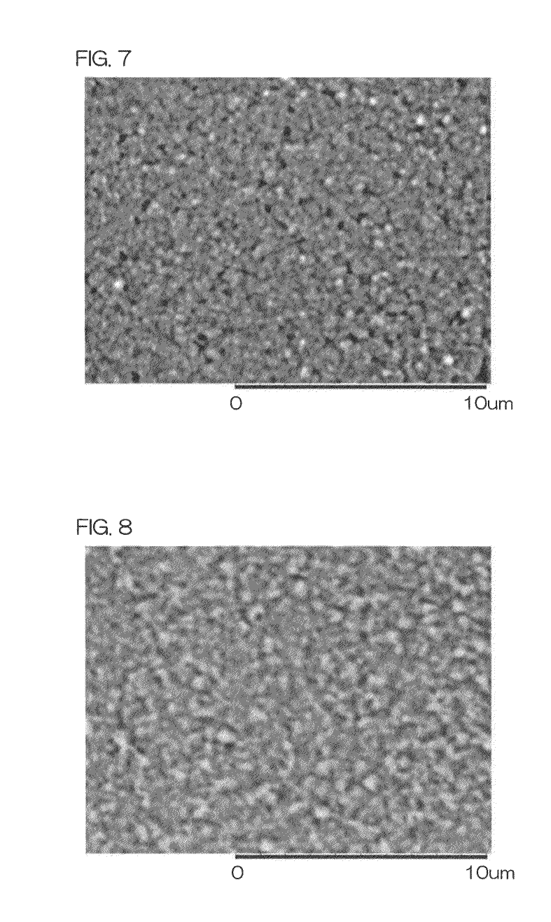

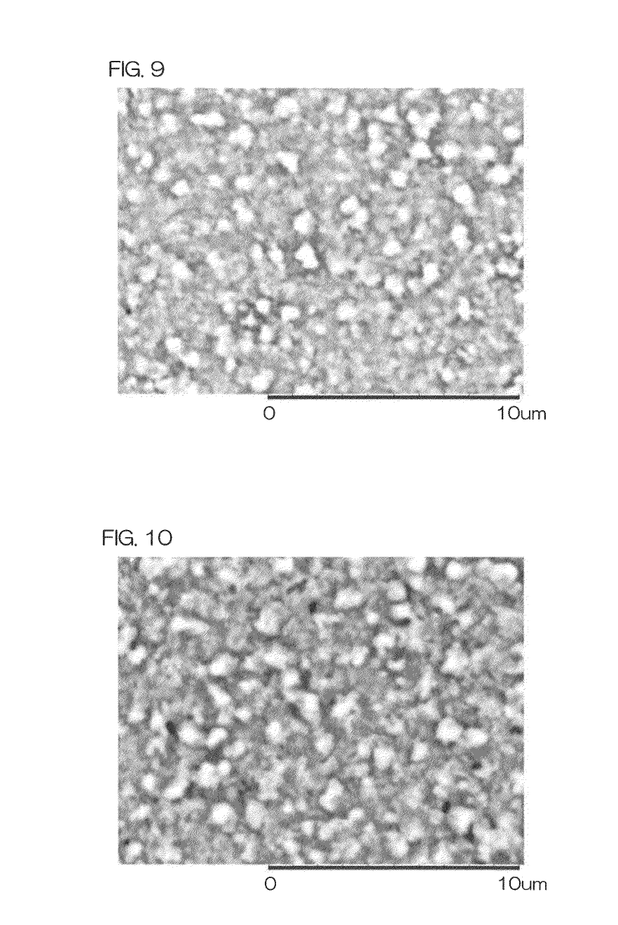

SEM images of the CZTS thin-films after the thermal treatment are shown in FIG. 8 (Example 4), FIG. 9 (Example 5), and FIG. 10 (Example 6). It is seen that as compared with FIG. 7 (Comparative Example 1), the crystal grew due to the thermal treatment, and that as the gas heating temperature was increased, the crystal growth was facilitated. In FIG. 8, the average crystal grain diameter was 0.75 μm. In FIG. 9, the average crystal grain diameter was 0.79 μm. In FIG. 10, the average crystal grain diameter was 1.13 μm.

### Comparative Example 2

The CZTS thin-film was manufactured under the same conditions as those in Example 6, and the thermal treatment was performed on the CZTS thin-film under the same conditions as those in Example 6 except that the temperature of the interior 1a for the heating of the substrate, where the substrate for the CZTS thin-film was set, was set at 50° C.

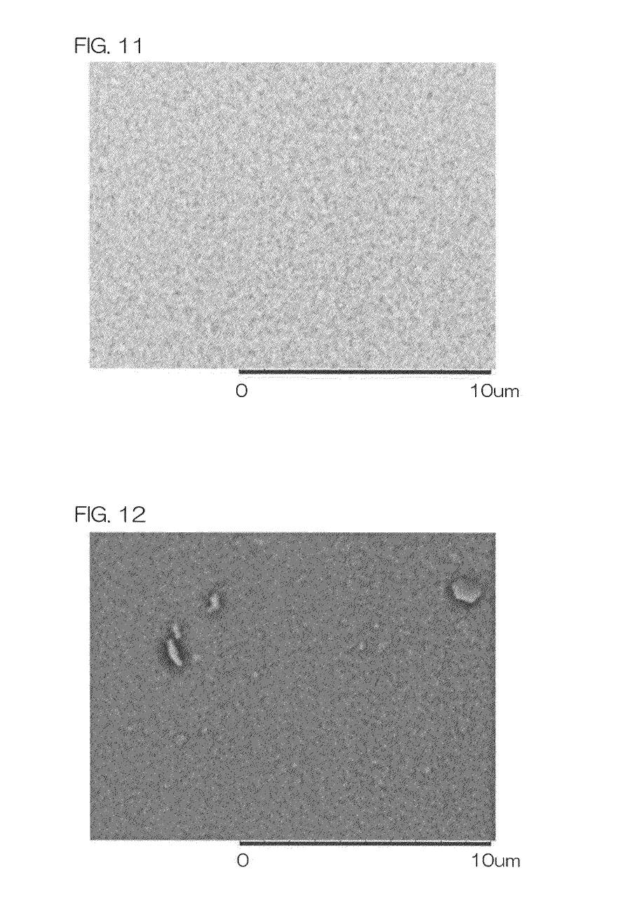

An SEM image of the CZTS thin-film before the thermal treatment is shown in FIG. 11, and an SEM image of the CZTS thin-film after the thermal treatment is shown in FIG. 12. It is seen from FIGS. 11 and 12 that the average crystal grain diameter in both cases was 0.05 μm or less, and remained substantially the same before and after the thermal treatment. Although a large aggregation is seen in FIG. 12, this is sulfur particles derived from H₂S.

It is seen from the results of Comparative Example 2 that when the temperature of the substrate of the CZTS thin-film was low at the time of the thermal treatment, the crystal growth of the CZTS thin-film is hardly recognizable. It is thought that the sulfur particles were adhered because the temperature of the substrate was low.

### REFERENCE CHARACTER LIST

1 . . . Chamber
1a . . . interior on downstream side
1b . . . interior on upstream side
2a . . . discharge port
2b . . . introduction port
3 . . . heat-resistant container
4a, 4b . . . temperature detection portion
5 . . . stage
6 . . . substrate
H1, H2 . . . electric heater

1. A method of manufacturing a compound semiconductor thin-film, comprising:
(a) preparing a substrate in which a or I-II-IV-VI compound semiconductor thin-film is formed on a surface thereof;
(b) setting the substrate within a chamber, and heating the substrate so that a first temperature of the substrate becomes 100° C. to 700° C.; and
(c) flowing a non-oxidizing gas heated to a second temperature that is higher than the first temperature within the chamber, and thermally treating the compound semiconductor thin-film formed on the surface of the substrate.

2. The method according to claim 1, wherein the second temperature of the non-oxidizing gas is higher than the first temperature of the substrate by 100° C. to 800° C.

3. The method according to claim 1,
wherein in the step (c), one type or more types of metal compounds are flowed together with the non-oxidizing gas, the metal compounds being selected from a group consisting of a sulfide, a selenide, an oxide, a salt, an alkylide, and a complex of the metal which constitutes the compound semiconductor thin-film.

4. The method according to claim 1,
wherein the second temperature of the non-oxidizing gas is 500° C. to 1000° C.

5. The method according to claim 1,
wherein the non-oxidizing gas is one type or more types of gases selected from a group consisting of nitrogen, argon, helium, hydrogen, hydrogen sulfide, and hydrogen selenide.

6. The method according to claim 1,
wherein either of sulfur and selenium or a mixture thereof is flowed together with the non-oxidizing gas.

7. The method according to claim 1,
wherein the substrate is a substrate in which the I-III-VI or I-II-IV-VI compound semiconductor thin-film is formed on a base member to which conductivity is applied in at least a part of a surface or an entire surface of the base member.

8. The method according to claim 1,
wherein the I-III-VI or I-II-IV-VI compound semiconductor is selected from a group consisting of Cu—In—S, Cu—In—Se, Cu—In—Ga—S, Cu—In—Ga—Se, Cu—Zn—Sn—S, Cu—Zn—Sn—Se, a mixture thereof, or a solid solution thereof.

9. The method according to claim 1,
wherein an average crystal grain diameter of the compound semiconductor thin-film obtained is 200 nm to 5 μm.

10. A compound semiconductor thin-film, manufactured by:
(a) preparing a substrate in which a I-III-VI or I-II-IV-VI compound semiconductor thin-film is formed on a surface thereof;
(b) setting the substrate within a chamber, and heating the substrate so that a first temperature of the substrate becomes 100° C. to 700° C.; and
(c) flowing a non-oxidizing as heated to a second temperature that is higher than the first temperature within the chamber, and thermally treating the compound semiconductor thin-film formed on the surface of the substrate,
wherein an average crystal grain diameter is 200 nm to 5 μm.

11. The compound semiconductor thin-film according to claim 10, wherein a crystal structure of the compound semiconductor is a chalcopyrite type or a kesterite type.

12. A photovoltaic device, comprising the compound semiconductor thin-film according to claim 10 that functions as a light absorbing layer.

13. A manufacturing device of a compound semiconductor thin-film, the device comprising:
a chamber that accommodates a substrate in which a or I-II-IV-VI compound semiconductor thin-film is formed on a surface thereof;
a first heater that heats such that a first temperature of the substrate becomes 100° C. to 700° C.; and
an introduction port that introduces, into the chamber, a non-oxidizing gas heated to a second temperature that is higher than the first temperature of the substrate,
wherein the compound semiconductor thin-film formed on the surface of the substrate is thermally treated.

14. The manufacturing device according to claim 13, further comprising a second heater that heats the non-oxidizing gas to the second temperature.

15. The manufacturing device according to claim 13,
wherein the chamber includes a first interior and a second interior connecting to each other, wherein the non-oxidizing gas is heated to the second temperature in the first interior that is disposed on an upstream side, the substrate is heated to the first temperature in the second interior that is disposed on a downstream side, and wherein the non-oxidizing gas is flowed from the first interior to the second interior.
